(19) United States
(12) Patent Application Publication
(10) Pub. No.: US 2026/0354180 A1
(43) Pub. Date: Nov. 5, 2026

(54) ENHANCED ENCAPSULATION ASSOCIATED WITH A SEMICONDUCTOR ASSEMBLY

(71) Applicants: Rohm Co., Ltd., Kyoto-shi (JP); Arieca, Inc., Pittsburgh, PA (US)

(72) Inventors: Navid KAZEM, Pittsburgh, PA (US); Tomoya YAMASHIKI, Sausalito, CA (US); Cara ROSSETTI, Pittsburgh, PA (US); Dylan SHAH, Pittsburgh, PA (US); Loren RUSSELL, Pittsburgh, PA (US)

(73) Assignees: Rohm Co., Ltd., Kyoto-shi (JP); Arieca, Inc., Pittsburgh, PA (US)

(21) Appl. No.: 19/194,860

(22) Filed: Apr. 30, 2025

(51) Int. Cl. H10W 40/25; H10W 74/01

(52) U.S. Cl. CPC H10W 40/257; H10W 74/01

(57) ABSTRACT

A semiconductor assembly may include a first layer, a second layer, a first material, and a second material. The first layer may be configured to transfer heat and second layer may be configured to dissipate at least a portion of the heat. The first material may include liquid metal droplets and a polymer, and may be disposed in contact with the first layer and the second layer. The first material may be configured to decrease at least one of a contact resistance or thermal resistance between the first layer and the second layer. The second material may be disposed in proximity to the first material, and may be configured to at least partially encapsulate the first material enhancing a stability of the first material and preventing exudation of at least one of the liquid metal droplets or the polymer from the first material based on one or more conditions.

### BACKGROUND

Electronic devices, such as semiconductor devices, generate heat during operation. Excessive heat may lead to performance degradation, accelerated material aging, or damage to one or more components of the electronic device. Accordingly, thermal management techniques may be employed to control and dissipate the heat generated during operation.

### SUMMARY

Some implementations described herein relate to a method, comprising: disposing a first material, including liquid metal droplets and a polymer, between a first layer and a second layer of a semiconductor assembly, wherein the first layer includes a region configured to conduct heat generated by a heat-generating component of the semiconductor assembly, and wherein the second layer is configured to facilitate dissipation of at least a portion of the heat from the region; disposing a second material in proximity to the first material; and causing: the first material to flow and conform to at least a portion of the region and a portion of the second layer such that the first material thermally couples the region and the second layer to decrease at least one of contact resistance or thermal resistance between the region and the second layer, and the second material to at least partially encapsulate the first material to enhance a stability of the first material and to prevent exudation of at least one of the liquid metal droplets or the polymer from the first material based on one or more conditions.

Some implementations described herein relate to a semiconductor assembly, comprising: a first layer; a heat-generating component disposed on the first layer, wherein the first layer is configured to transfer heat generated by the heat-generating component; a second layer configured to facilitate dissipation of at least a portion of the heat from the first layer; a first material, including liquid metal droplets and a polymer, disposed in contact with the first layer and the second layer to thermally couple the first layer and the second layer, wherein the first material is configured to decrease at least one of a contact resistance or thermal resistance between the first layer and the second layer; and a second material, disposed in proximity to the first material, configured to at least partially encapsulate the first material to enhance a stability of the first material and to prevent exudation of at least one of the liquid metal droplets or the polymer from the first material based on one or more conditions.

Some implementations described herein relate to a semiconductor assembly, comprising: a package including an exterior surface; a first component, disposed within the package, configured to perform power conversion operations, wherein the exterior surface is configured to transfer heat generated based on the power conversion operations; a second component disposed in proximity to the exterior surface, configured to dissipate at least a portion of the heat from the exterior surface; a first material, including liquid metal droplets and a polymer, disposed in contact with the exterior surface and the second component to thermally couple the exterior surface and the second component, wherein the first material is configured to decrease at least one of contact resistance or thermal resistance between the exterior surface and the second component; and a second material, disposed in proximity to the first material, configured to at least partially encapsulate the first material to enhance a stability of the first material and to prevent exudation of at least one of the liquid metal droplets or the polymer from the first material based on one or more conditions.

### BRIEF DESCRIPTION OF THE DRAWINGS

FIG. 1 is a flowchart of an example process associated with enhanced encapsulation associated with a semiconductor assembly.

FIGS. 2A-2D are diagrams of an example associated with enhanced encapsulation associated with a semiconductor assembly.

FIGS. 3A-3E are diagrams of an example associated with enhanced encapsulation associated with a semiconductor assembly.

FIGS. 4A-4C are diagrams of an example associated with enhanced encapsulation associated with a semiconductor assembly.

FIGS. 5A-5B are diagrams of an example associated with enhanced encapsulation associated with a semiconductor assembly.

### DETAILED DESCRIPTION

The following detailed description of example implementations refers to the accompanying drawings. The same reference numbers in different drawings may identify the same or similar elements.

In semiconductor manufacturing, a variety of materials may be employed for various functions, such as thermal management, encapsulation, adhesion, and/or electrical insulation associated with a semiconductor assembly. For example, a thermal interface material (TIM) may be disposed between two surfaces (e.g., in contact with the two surfaces) to improve thermal conduction by reducing contact resistance and/or thermal resistance (e.g., between the two surfaces). A TIM may be a composite material that includes one or more mobile phases (e.g., liquid metal droplets) distributed throughout a matrix (e.g., dispersed within a polymer matrix or an elastomeric binder, among other examples), which acts as a structural phase (e.g., a continuous structural phase) to stabilize the mobile phases and maintain the material integrity (e.g., during and/or after application).

In some cases, the mobile phases may undergo exudation, which may also be referred to herein as bleedout or leakage, where the mobile phases separate from the matrix and migrate toward adjacent surfaces, interfaces, and/or voids. Exudation may occur when the composite material is disrupted or degraded, such as due to mechanical stress, thermal cycling, chemical interaction, and/or environmental conditions. Exudation of the mobile phases and/or the matrix from the composite material may negatively affect one or more intended functions of the TIM, such as thermal conductivity and/or adhesion, and may lead to adverse effects including contamination, delamination, and reduced reliability of one or more components of the semiconductor assembly.

Some implementations described herein provide enhanced encapsulation associated with a semiconductor assembly. The described approach introduces a novel method for stabilizing thermal interface materials (TIMs), particularly those incorporating liquid metal droplets, through the use of a secondary encapsulation material. This secondary material is strategically positioned to at least partially surround the TIM, thereby preventing migration of the liquid metal droplets and improving the stability of the TIM under various stress conditions. Additionally, the encapsulation material serves to shield the TIM from external environmental factors, such as chemical exposure or physical damage, while preserving the thermal conductivity and mechanical integrity of the TIM.

In certain implementations, the described method facilitates the application of encapsulation material alongside the thermal interface material (TIM) to promote effective thermal coupling between heat-generating components and heat-dissipating structures. The encapsulation material is configured to adapt to the geometry of the TIM and surrounding surfaces, forming a durable barrier that prevents leakage while enabling the TIM to perform its intended role. By overcoming the shortcomings of existing TIM solutions, the described approach provides a dependable and effective thermal management system for semiconductor devices functioning under demanding conditions.

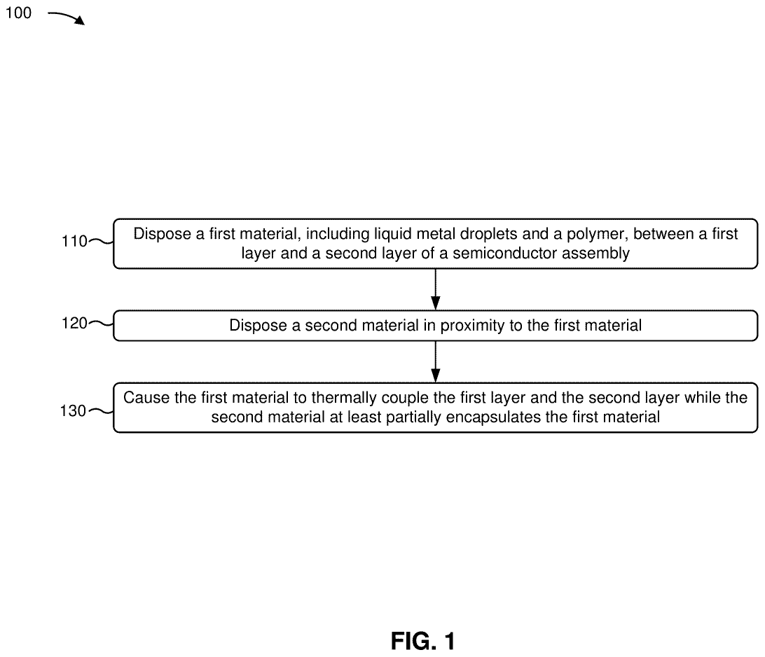

FIG. 1 is a flowchart of an example process 100 associated with enhanced encapsulation associated with a semiconductor assembly. As shown in FIG. 1, the process 100 may include disposing a first material between a first layer and a second layer of a semiconductor assembly (block 110).

In some implementations, the first material may be a TIM including liquid metal droplets and a polymer (e.g., the first material may be an emulsion of a polymer and the liquid metal droplets, among other examples). Accordingly, the liquid metal droplets may be mobile phases and the polymer may be a structural phase (e.g., a continuous structural phase) that stabilizes the mobile phases and maintains material integrity, such as retaining a dispersion of the mobile phases and preserving a functional performance of the TIM (e.g., over time and under one or more conditions).

As used herein, the terms “material integrity” may refer to an ability of the TIM to maintain one or more properties during manufacturing, installation, and/or operation, such as thermal conductivity, mechanical stability, dimensional stability, and/or adhesion, among other examples. For example, material integrity may be associated with a resistance of the TIM to degradation mechanisms, such as exudation (e.g., bleedout or leakage) of the mobile phases and/or the matrix, delamination, fracture, and/or phase separation, and an ability of the TIM to withstand thermal cycling, compression, vibration, and/or chemical exposure, among other examples.

Maintaining the material integrity of the TIM aids in providing thermal coupling between the first layer and the second layer, which prevents performance loss or reliability issues in the semiconductor assembly. Although the first material is described as being a TIM including liquid metal droplets and a polymer, the first material may include any suitable materials configured to provide thermal coupling associated with the semiconductor assembly, such as a TIM including thermally conductive fillers (e.g., thermally conductive particles) dispersed within a carrier matrix, among other examples.

In some implementations, the TIM may be disposed on the second layer at a location (e.g., in an uncured state, among other examples). The first material may have a first height (e.g., a distance between a surface to which the TIM is disposed and a top surface of the TIM). Although the TIM is described as being disposed on the second layer at a first location, the TIM may be disposed on any suitable surface of the semiconductor assembly at any suitable location in any suitable state, such as being disposed on the first layer at a second location in an uncured state, among other examples.

In some implementations, and to dispose the TIM on the second layer at the first location, the TIM may be deposited onto a surface of the second layer, such as being deposited as a TIM pad covering a portion of the surface of the second layer (e.g., at the location). For example, the TIM may be deposited via a slit coater or a stencil coater, among other examples. In some implementations, a mass of the TIM (e.g., deposited on the second layer) may be approximately 0.7 grams. Although the mass of the TIM is described as being approximately 0.7 grams, the mass of the TIM (e.g., deposited on the second layer) may be any suitable mass.

In some implementations, the first layer may include a region, which may also be referred to herein as a heat transfer region, configured to conduct heat generated by a heat-generating component of the semiconductor assembly. For example, the region may be an integrated heat spreader configured to transfer heat generated by the heat-generating component across a surface of the integrated heat spreader. As another example, the region may be a surface of the heat-generating component configured to transfer heat generated by the heat-generating component.

In some implementations, the heat-generating component may include a silicon carbide (SiC) semiconductor device configured for power conversion, such as power conversion at high operating voltages. As used herein, the term “high operating voltages” may refer to operating voltages of at least approximately 200 volts. For example, the heat-generating component may be an SiC semiconductor device used in traction inverters (e.g., for electric vehicle drivetrains), onboard chargers (e.g., for recharging vehicle battery systems), photovoltaic (PV) inverters (e.g., for solar energy conversion systems), and/or electric vehicle charging stations (e.g., for high-power DC fast charging), among other applications. Operation of the SiC semiconductor device at the high operating voltages may expose the SiC semiconductor device to one or more conditions, such as one or more conditions associated with thermal cycling, temperature fluctuations, material expansion, and/or material contraction (e.g., during repeated operational on/off or load-shift cycles, among other examples).

In some implementations, the one or more conditions may include at least one of a thermal condition (e.g., related to temperature cycling or localized heating during high-power operation), a mechanical condition (e.g., related to vibration or shock resulting from vehicular motion or road impact), an electrical condition (e.g., related to high-voltage transients, switching noise, and/or partial discharge events), an environmental condition (e.g., related to exposure to humidity, condensation, dust, and/or corrosive atmospheres), and/or an operational condition (e.g., related to prolonged operation under fluctuating load profiles or rapid acceleration/deceleration cycles in electric vehicle powertrains).

Although the heat-generating component is described herein as an SiC-based semiconductor device configured for performing power conversion operations at high operating voltages, the heat-generating component may include any suitable electronic component configured to generate heat as a result of operating under any suitable operating conditions (e.g., any suitable operating voltages).

In some implementations, the second layer may be configured to dissipate at least a portion of the heat transferred from the first layer through the TIM (e.g., transferred from the region through the TIM to be dissipated by the second layer). For example, the second layer may include a heat-dissipating component, such as a heat sink, metal plate, or base plate, among other examples. The TIM may be configured to thermally couple the first layer and the second layer, which reduces contact resistance and/or thermal resistance between the first layer and the second layer and enhances heat transfer efficiency in the semiconductor assembly, among other examples.

As further shown in FIG. 1, the process 100 may include disposing a second material in proximity to the first material (block 120). For example, the second material may be disposed at a location that allows the second material to at least partially encapsulate the TIM (e.g., after undergoing further processing, as described in more detail elsewhere herein), such as by enclosing, surrounding, bordering, or overlaying the TIM after undergoing processing.

In some implementations, the second material may be associated with one or more characteristics (e.g., one or more physical and/or chemical characteristics, among other examples) that enable the second material to conform to, deform around, and/or bond to surrounding surfaces in a manner that creates a containment region for the first material. In this way, the second material may be configured to enhance a stability of the first material and to prevent exudation of the liquid metal droplets and/or the polymer from the first material based on one or more conditions, such as those encountered in high-voltage applications, as described in more detail elsewhere herein. By maintaining a physical seal or geometric barrier, the second material may prevent exudation of the liquid metal droplets and/or the polymer from the first material and help preserve the mechanical integrity and thermal conductivity of the first material.

In some implementations, the second material may be a conformable material (e.g., a soft, elastomeric silicone that conforms to surface irregularities), a deformable material (e.g., a compressible adhesive material that deforms under load and maintains at least partial perimeter sealing), a structurally stabilized material (e.g., a rigid-backed adhesive material providing shape retention and/or geometric control), and/or a flow-solidifying material (e.g., a hot melt adhesive and/or a curable silicone that transitions from flowable to solid after deposition), among other examples.

For example, the second material may be a room-temperature-vulcanizing material, a compressible adhesive material, a compressible rigid-backed dam, a pick-and-place dam, a multilayer pad, a tape (e.g., an adhesive tape), a polymer, a flexible material, and/or a hot melt adhesive material (e.g., disposed on at least one of the first layer or the second layer), among other examples.

In some implementations, the second material may be capable of reducing a modulus of the second material (e.g., a value indicative of stiffness or resistance to deformation under applied stress), such as in response to one or more conditions (e.g., one or more thermal, mechanical, electrical, environmental, and/or operational conditions, among other examples). A reduction in the modulus may enable the second material to absorb or redistribute stress more effectively under such conditions, which aids in mitigating or preventing damage (e.g., cracking and/or delamination) to the second material.

As further shown in FIG. 1, the process 100 may include causing the first material to thermally couple the first layer and the second layer and cause the second layer to at least partially encapsulate the first material (block 130), as described in more detail elsewhere herein. In some implementations, the semiconductor assembly may undergo processing that causes the first material to thermally couple the first layer and the second layer to at least partially encapsulate the first material. For example, compression forces and/or heat may be applied to the semiconductor assembly causing the first material to flow and conform to portions of the first layer and the second layer, and which causes the second material to at least partially encapsulate the first material (e.g., the second material may form, along with the first layer and the second layer, at least a partial boundary around the first material), as described in more detail elsewhere herein.

In some implementations, the first material may be disposed (e.g., deposited) between the first layer and the second layer of the semiconductor assembly prior to the disposition (e.g., deposition) of the second material. In some other implementations, the second material may be disposed (e.g., deposited) before the first material. In yet some other implementations, the first material and the second material may be disposed substantially simultaneously (e.g., using coordinated deposition techniques and/or multi-nozzle systems, among other examples. During subsequent processing (e.g., by applying compression forces and/or heat), the first material and/or the second material may undergo motion. For example, the first material may flow and conform to at least a portion of the region of the first layer and a portion of the second layer to reduce contact resistance and/or thermal resistance, while the second material may deform or reflow to encapsulate the first material. This interaction may enhance the stability of the first material and prevent exudation of the liquid metal droplets and/or polymer under one or more conditions, as described in more detail elsewhere herein.

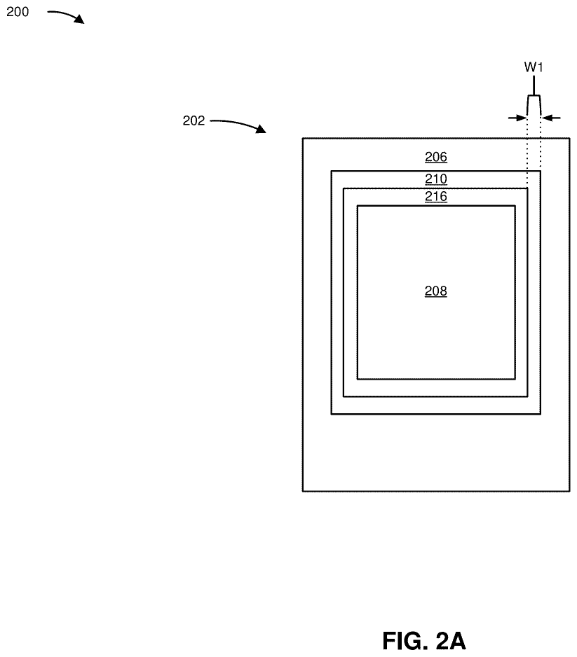

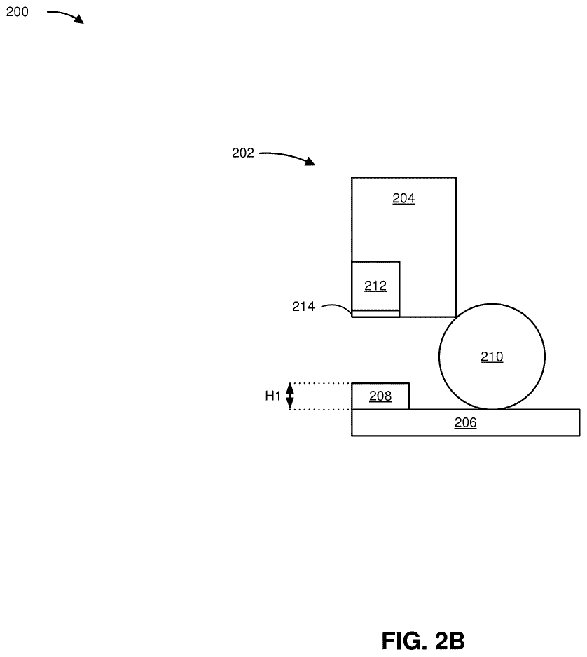

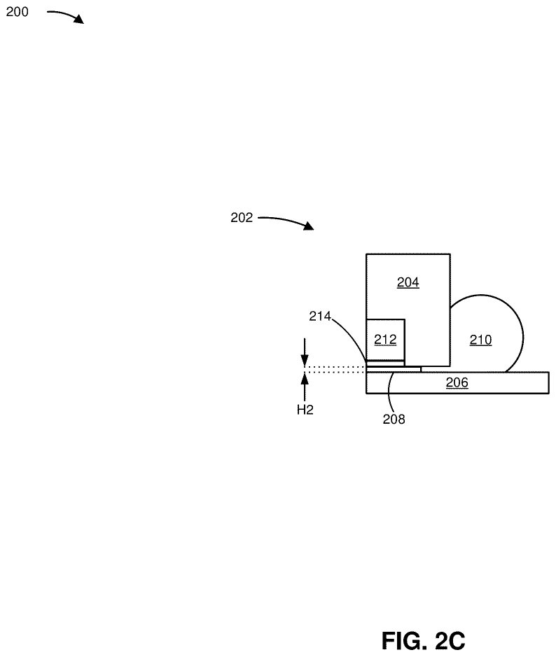

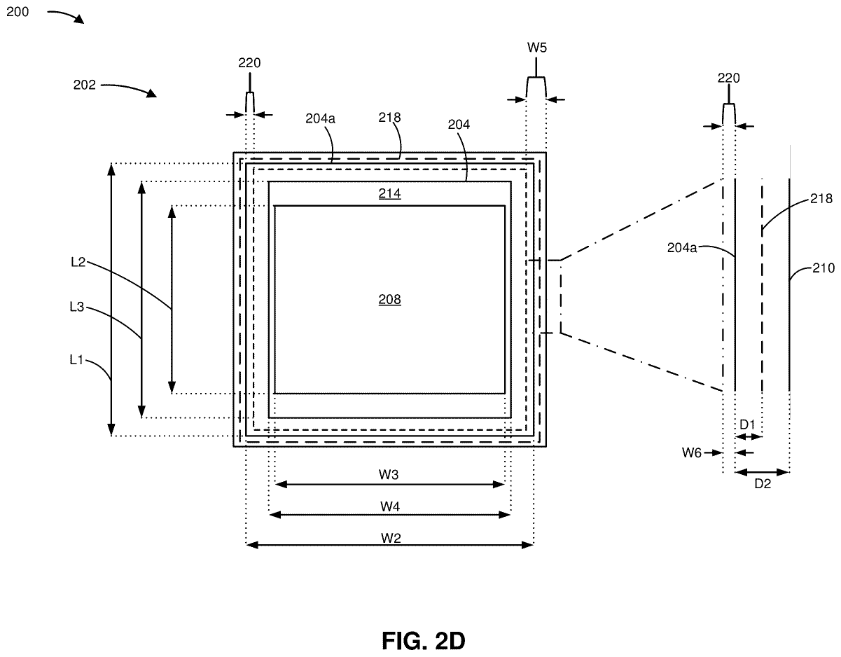

Although FIG. 1 shows example blocks of the process 100, in some implementations, the process 100 may include additional blocks, fewer blocks, different blocks, or differently arranged blocks than those depicted in FIG. 1. Additionally, or alternatively, two or more of the blocks of process 100 may be performed in parallel. The process 100 is an example of one process that may be performed by one or more devices described herein. These one or more devices may perform one or more other processes based on operations described herein, such as the operations described in connection with FIGS. 2A-5B. Moreover, while the process 100 has been described in relation to the devices and components of the preceding figures, the process 100 can be performed using alternative, additional, or fewer devices and/or components. Thus, the process 100 is not limited to being performed with the example devices, components, hardware, and software explicitly enumerated in the preceding figures.

FIGS. 2A-2D are diagrams of an example 200 associated with enhanced encapsulation associated with a semiconductor assembly. As shown in FIGS. 2A-2D, the example 200 includes a semiconductor assembly 202. The semiconductor assembly 202 may include a first layer 204, a second layer 206, a first material 208, and a second material 210.

In some implementations, the first material 208 may be a TIM including liquid metal droplets and a polymer and the second material 210 may be a room-temperature vulcanizing material (e.g., a room-temperature-vulcanizing silicone, among other examples), as described in more detail elsewhere herein.

As further shown in FIG. 2A, the first material 208 may be disposed on the second layer 206 at a location (e.g., a central location of a surface of the second layer 206). For example, the first material 208 may be deposited as a TIM pad at a location on a surface of the second layer 206 (e.g., using a slit coater or a stencil coater, among other examples). In a slit coating implementation, the first material 208 may be extruded through a slot die to form a coating layer (e.g., a uniform coating layer with a defined width and thickness). In a stencil coating implementation, the first material 208 may be applied through an aperture in a stencil layer, where the stencil may define a pad footprint.

In some implementations, a mass of the first material 208 disposed on the second layer 206 may be approximately 0.7 grams. Although the mass of the first material 208 disposed on the second layer 206 is described as being approximately 0.7 grams, the mass of the first material 208 may be any suitable mass, such as a mass in a range of approximately 0.6 grams and 0.8 grams, among other examples.

As further shown in FIG. 2A, the second material 210 may be disposed at a location on the surface of the second layer 206 in proximity to the first material 208. In some implementations, the second material 210 may be dispensed as a bead along a path (e.g., a predefined path) forming a containment region 216 around the first material 208 (e.g., the containment region 216 may include a portion of the surface of the second layer 206). As an example, the bead may be deposited following a centerline of the path (shown as a centerline 218 of the dispense path is shown in FIG. 2D). The bead may have an initial width (e.g., shown as W1 in FIG. 2A) and an initial height (e.g., defined by a dispense rate, a nozzle diameter, and/or a traverse speed, among other examples). In some implementations, the bead may form a closed or partially open perimeter around the first material 208 to provide exudation control, enhanced bonding, and/or mechanical isolation, among other examples.

As shown in FIG. 2B, the first layer 204 may include a heat-generating component 212 and a region 214. The heat-generating component 212 may be configured to generate heat (e.g., generated as a result of performing operations, such as power conversion operations, among other examples) and the region 214 may be configured to transfer at least a portion of the heat (e.g., across a surface of the region 214) generated by the heat-generating component 212. The second layer 206 may be configured to dissipate at least a portion of the heat from the region 214 through the first material 208, as described in more detail elsewhere herein.

As further shown in FIG. 2B, the semiconductor assembly 202 may be in a first state representing a first configuration (e.g., a pre-assembled configuration as shown in FIG. 2B) in which the first material 208 and the second material 210 are disposed between the first layer 204 and the second layer 206 (e.g., without mechanical engagement among one or more components of the semiconductor assembly 202). As further shown in FIG. 2B, the first material 208 may have a first height (e.g. shown as H1 in FIG. 2B), such as after being deposited on the second layer 206.

In some implementations, the semiconductor assembly 202 may be associated with a geometry. For example, and when the semiconductor assembly 202 is in the first state, the first layer 204 may have a length (e.g., shown as L1) and a width (e.g., shown as W2), the first material 208 may have a length (e.g., shown as L2) and a width (e.g., shown as W3), and the region 214 may have a length (e.g., shown as L3) and a width (e.g., shown as W4). As an example, the length of the first layer 204 may be approximately 52.5 millimeters and the width of the first layer may be approximately 41.5 millimeters, the length of the first material 208 may be approximately 33 millimeters and the width of the first material 208 may be approximately 40 millimeters, the length of the region 214 may be approximately 43 millimeters, and the width of the region 214 may be approximately 37 millimeters. Although one or more components of the semiconductor assembly 202 are described as having particular dimensions, the one or more components of the semiconductor assembly 202 may have any suitable dimensions.

In some implementations, compression forces and/or heat may be applied to the semiconductor assembly 202 to transition the semiconductor assembly 202 from the first state to a second state representing a second configuration (e.g., an assembled configuration as shown in FIG. 2C). In some implementations, the assembled configuration may be a semiconductor package, such as a molded semiconductor package, among other examples.

As further shown in FIG. 2C, the compression forces and/or the heat may cause the first material 208 to flow and conform to the region 214 and the second layer 206 (e.g., the first material 208 may be configured to flow and conform to the region 214 and the second layer 206 in response to application of at least one of a compression force or heat). In other words, the first material 208 may spread laterally from the location (e.g., an original deposition area) into previously uncovered portions of the containment region 216 to thermally couple the region 214 and the second layer 206. Additionally, the height of the first material 208 may decrease from the first height to a second height (e.g., shown as H2 in FIG. 2C), which may correspond to a desired bond line thickness (BLT), such as a BLT in a range of approximately 40 microns and 50 microns, among other examples.

Furthermore, the compression forces may the cause bead (e.g., of the second material 210) to undergo lateral deformation, which increases the first width of the second material 210 to a second width (e.g., shown as W5 in FIG. 2D). This results in a height of the second material 210 matching, or being similar to, the second height H2 of the first material 208 (e.g., which corresponds to the desired BLT).

In some implementations, the first layer 204 may include a peripheral edge (e.g., shown as a peripheral edge 204a in FIG. 2D) and the second material 210 may contact a peripheral region (e.g., shown as a peripheral region 220 in FIG. 2D) of the surface of the first layer 204 that is adjacent to the peripheral edge 204a, such as after being compressed. In other words, the second material 210 may be configured to contact the peripheral region 220 along a length of the peripheral edge 204a (e.g., along a majority of the length of the peripheral edge 204a, among other examples).

In some implementations, a width (e.g., shown as W6 in FIG. 2D) of the peripheral region 220 may be approximately 0.6 millimeters. Although the width of the peripheral region 220 is described as being approximately 0.6 millimeters, the width of the peripheral region 220 may be in a range of approximately 0.3 millimeters and 0.9 millimeters, among other examples. In some implementations, the height of the second material 210 may be in a range of approximately 1 millimeter and approximately 2 millimeters to prevent exudation of the liquid metal droplets and/or the polymer from the first material 208. Although the height of the second material 210 is described as being in a range of approximately 1 millimeter and approximately 2 millimeters, the height of the second material 210 may be any suitable height to prevent exudation of the liquid metal droplets and/or the polymer from the first material 208.

In some implementations, a distance (e.g., shown as D1) between the centerline 218 and the peripheral edge 204a may be approximately 0.9 millimeters and a distance (e.g., shown as D2 in FIG. 2D) between the peripheral edge 204a and an outer edge of the bead may be approximately 3 millimeters. Although a distance between the centerline 218 and the peripheral edge 204a is described as being approximately 0.9 millimeters and a distance between the peripheral edge 204a and an outer edge of the bead is described as being approximately 3 millimeters, the distance between the centerline 218 and the peripheral edge 204a and the distance between the peripheral edge 204a and an outer edge of the bead may be any suitable distances.

Accordingly, and in some implementations, the first material 208 may contact and thermally couple to the region 214 (e.g., an entirety of a surface of the region 214, among other examples) and may contact and thermally couple to a portion of the surface of the second layer 206. In this way, the first material 208 may be configured to reduce contact resistance and/or thermal resistance between the region 214 and the second layer 206. Additionally, the second material 210 may be configured to at least partially encapsulate the first material 208 to enhance stability of the first material 208 and prevent exudation of the liquid metal droplets and/or the polymer from the first material 208 (e.g., under thermal and/or mechanical stress, among other examples).

As indicated above, FIGS. 2A-2D are provided as an example. Other examples may differ from what is described with regard to FIGS. 2A-2D.

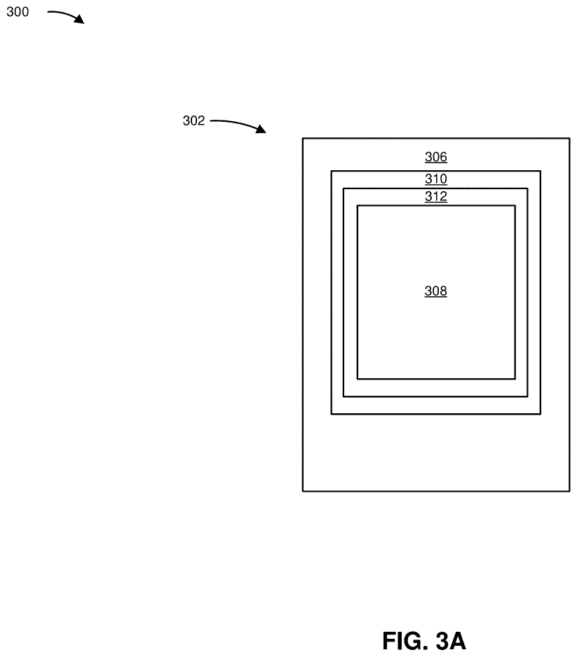

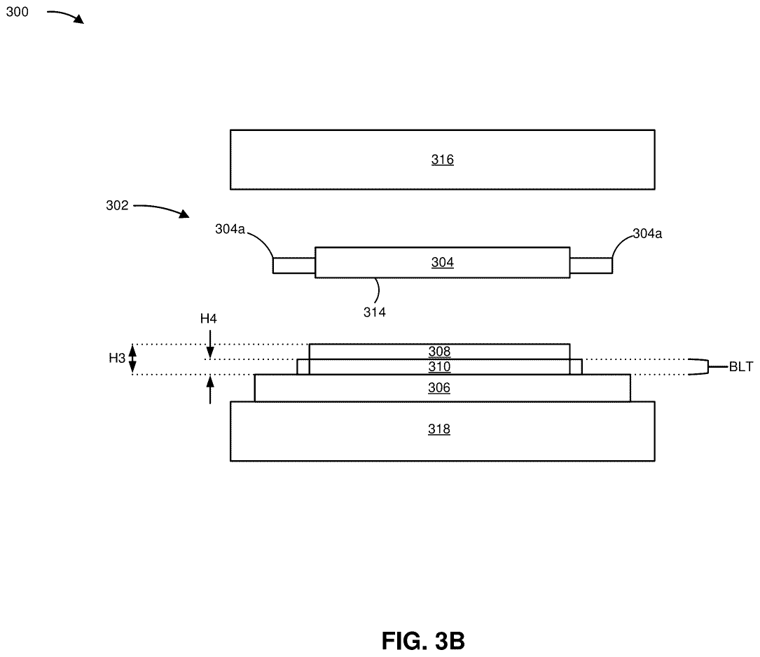

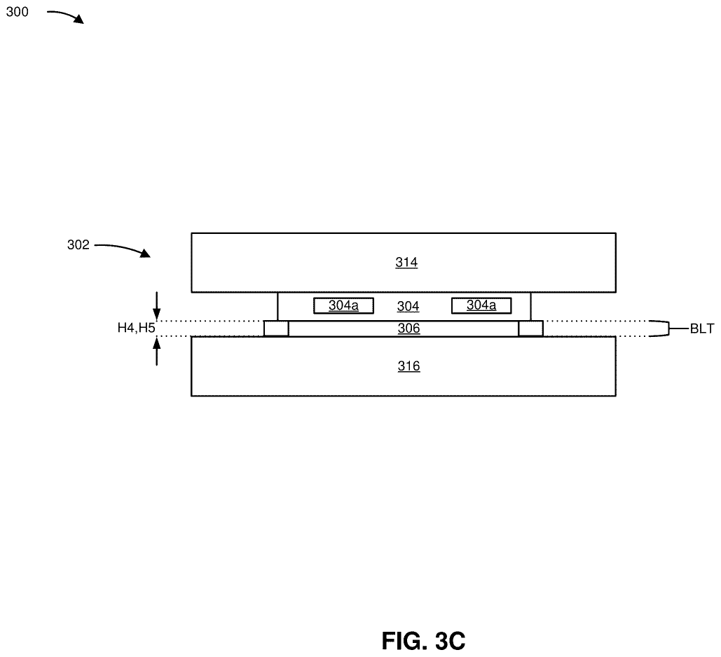

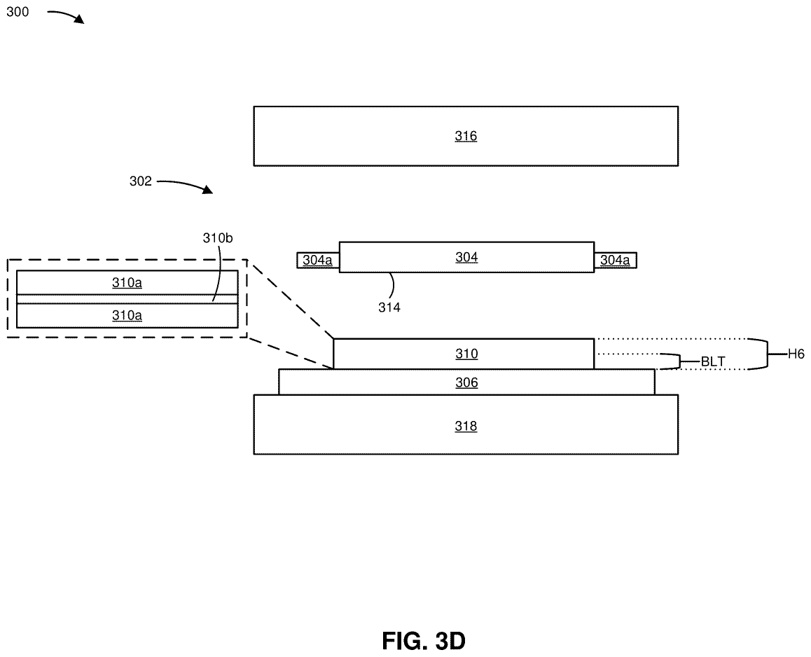

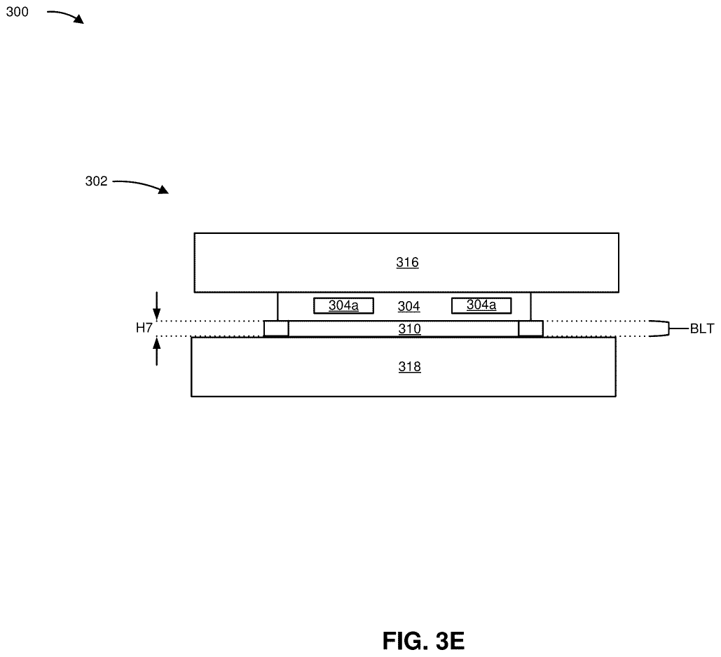

FIGS. 3A-3E are diagrams of an example 300 associated with enhanced encapsulation associated with a semiconductor assembly. As shown in FIGS. 3A-3E, the example 300 includes a semiconductor assembly 302. The semiconductor assembly 302 may include a first layer 304, a second layer 306, a first material 308, and a second material 310.

The first material 308 may be a TIM including liquid metal droplets and a polymer and the second material 310 may be a compressible structurally stabilized structure (e.g., a compressible rigid-backed adhesive dam, among other examples). For example, the second material 310 may be a double-coated adhesive tape, such as a polyethylene terephthalate (PET)-based double-coated adhesive tape (e.g., including two pressure-sensitive adhesive (PSA) layers, each having a thickness of approximately 60 microns, disposed on opposing sides of a PET carrier layer having a thickness of approximately 25 microns, among other examples).

As further shown in FIG. 3A, the first material 308 may be disposed on the second layer 306 at a location, as described in more detail elsewhere herein. As further shown in FIG. 3A, the second material 310 may be disposed at a location on the surface of the second layer 306 in proximity to the first material 308. In some implementations, the second material 310 may be pre-formed and applied as a patterned adhesive tape layer that defines a containment region 312 around the first material 308 (e.g., the containment region 312 may include a portion of the surface of the second layer 306). For example, the second material 310 may be applied as a perimeter, or a partial perimeter, shape to surround the first material 308 and provide exudation control, enhanced bonding, and/or mechanical isolation. In some implementations, the second material 310 may have matching, or similar, dimensions as the second material 210 shown and described in connection with FIGS. 2A-2D.

As shown in FIG. 3B, the first layer 304 may be a heat-generating component including terminals 304a (e.g., associated with performing power conversion operations) and a region 314 (e.g., a bottom surface of the heat-generating component). The heat-generating component may be configured to generate heat and the region 314 may be configured to transfer at least a portion of the heat (e.g., across a surface of the region 314). The second layer 306 may be configured to dissipate at least a portion of the heat from the region 314 through the first material 308, as described in more detail elsewhere herein.

As further shown in FIG. 3B, the semiconductor assembly 302 may be in a first state representing a first configuration (e.g., a pre-assembled configuration as shown in FIG. 3B) in which the first material 308 and the second material 310 are disposed between the first layer 304 and the second layer 306 (e.g., without mechanical engagement among one or more components of the semiconductor assembly 202). As further shown in FIG. 3B, the first material 308 may have a height (e.g. shown as H3 in FIG. 3B) and the second material 310 may have a height (e.g., shown as H4 in FIG. 3B), such as after being disposed on the second layer 306 that is less than the height of the first material 308.

In some implementations, compression forces and/or heat may be applied to the semiconductor assembly 302 to transition the semiconductor assembly 302 from the first state to a second state representing a second configuration (e.g., an assembled configuration as shown in FIG. 3C). In some implementations, the assembled configuration may be a semiconductor package, such as a molded semiconductor package, among other examples.

For example, the compression forces and/or the heat may be applied to the semiconductor assembly 302 via a heat press (e.g., shown as including a top press portion 316 and a bottom press portion 318 in FIGS. 3B-3C), among other examples.

The compression forces and/or the heat may cause the first material 308 to flow and conform to the region 314 and the second layer 306, as described in more detail elsewhere herein. After compression, the height of the first material 308 may be reduced to a height (e.g., shown as H5 in FIG. 3C) that matches the height of the second material 310, which may correspond to the desired BLT (e.g., shown as BLT in FIGS. 3B-3C).

In some implementations, the second material 310 may be configured to contact a peripheral region of the surface of the first layer 304, as described in more detail elsewhere herein. Accordingly, and in some implementations, the first material 308 may contact and thermally couple to the region 314 (e.g., an entirety of a surface of the region 314, among other examples) and may contact and thermally couple to a portion of the surface of the second layer 306.

In this way, the first material 308 may be configured to reduce contact resistance and/or thermal resistance between the region 314 and the second layer 306. Additionally, the second material 310 may be configured to at least partially encapsulate the first material 308 to enhance stability of the first material 308 and prevent exudation of the liquid metal droplets and/or the polymer from the first material 308 (e.g., under thermal and/or mechanical stress, among other examples).

As shown in FIG. 3D, and in some implementations, the second material 310 may include multiple layers (e.g., shown as two pressure-sensitive adhesive (PSA) layers 310a disposed on opposing sides of a PET carrier layer 310b). As further shown in FIG. 3D, a height (e.g., shown as H6 in FIG. 3D) of the second material 310 may be greater than or equal to a height of the first material 308. Compression forces and/or heat may be applied to the semiconductor assembly 302, as described in more detail elsewhere herein.

As shown in FIG. 3E, a height of the second material 310 may be reduced to a height (e.g., shown as H7 in FIG. 3E) that matches, or is similar to, a height of the first material 308, and that corresponds to the desired BLT. In this way, the first material 308 may contact and thermally couple to the region 314 (e.g., an entirety of a surface of the region 314, among other examples) and may contact and thermally couple to a portion of the surface of the second layer 306. In this way, the first material 308 may be configured to reduce contact resistance and/or thermal resistance between the region 314 and the second layer 306. Additionally, the second material 310 may be configured to at least partially encapsulate the first material 308 to enhance stability of the first material 308 and prevent exudation of the liquid metal droplets and/or the polymer from the first material 308 (e.g., under thermal and/or mechanical stress, among other examples).

As indicated above, FIGS. 3A-3E are provided as an example. Other examples may differ from what is described with regard to FIGS. 3A-3E.

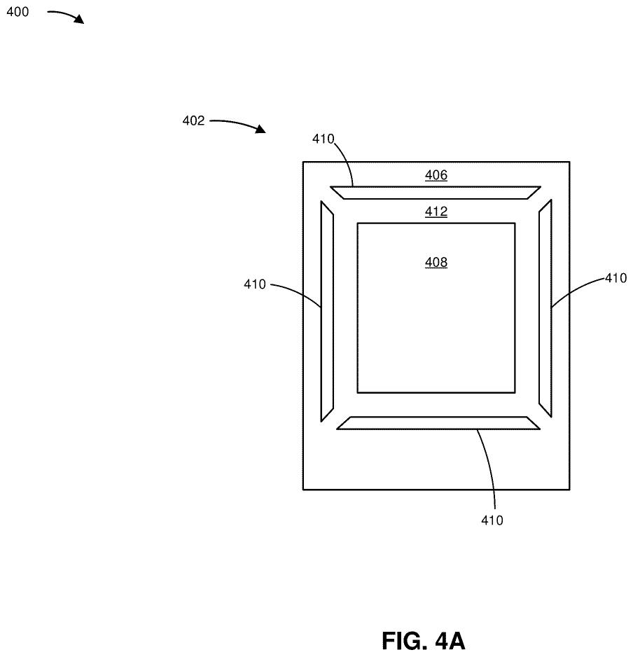

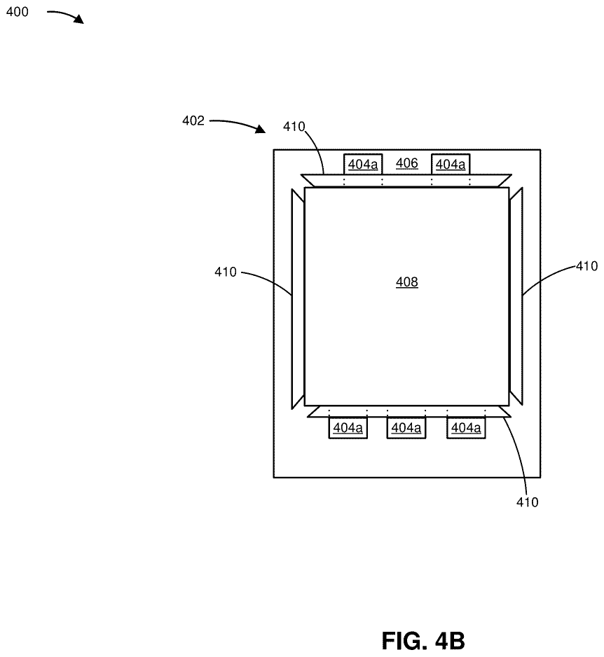

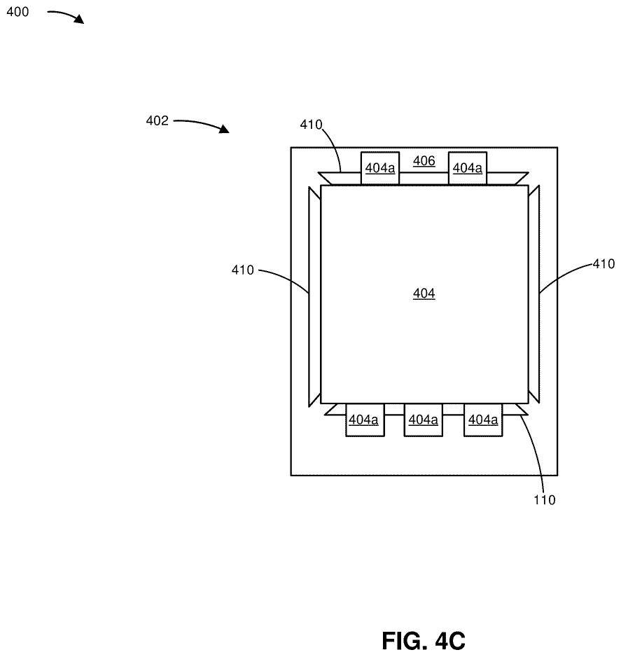

FIGS. 4A-4C are diagrams of an example 400 associated with enhanced encapsulation associated with a semiconductor assembly. As shown in FIGS. 4A-4C, the example 400 includes a semiconductor assembly 402. The semiconductor assembly 402 may include a first layer 404, a second layer 406, a first material 408, and a second material 410.

The first material 408 may be a TIM including liquid metal droplets and a polymer and the second material 410 may be a stencil-printed material, such as a room-temperature vulcanizing (RTV) material, among other examples. The first layer 404 may be configured to transfer heat (e.g., from a heat-generating component) across a surface of the first layer 104. The second layer 406 may be configured to dissipate at least a portion of the heat from the first layer 404 through the first material 408.

The first material 408 may be disposed on the second layer 406, as described in more detail elsewhere herein. The second material 410 may be printed around the first material 408 to form a continuous or segmented containment region (e.g., shown as a segmented containment region 412 in FIG. 4A).

In some implementations, compression forces and/or heat may be applied to the semiconductor assembly 402 to transition the semiconductor assembly 402 from a first state representing a first configuration (e.g., a pre-assembled configuration) to a second state representing a second configuration (e.g., an assembled configuration). For example, a first side of the assembled configuration is shown in FIG. 4B and a second side of the assembled configuration is shown in FIG. 4C). In some implementations, the assembled configuration may be a semiconductor package, such as a molded semiconductor package, among other examples.

In some implementations, a snap cure process may be applied to the semiconductor assembly 402 to cure (e.g., simultaneously cure) the first material 408 and compress the first material 408 and/or the second material 410 to a desired BLT. In this way, the first material 408 may be configured to thermally couple the first layer 404 and the second layer 406 to reduce contact resistance and/or thermal resistance between the first layer 404 and the second layer 406. Additionally, the second material 410 may be configured to at least partially encapsulate the first material 408 to enhance stability of the first material 408 and prevent exudation of the liquid metal droplets and/or the polymer from the first material 408 (e.g., under thermal and/or mechanical stress, among other examples).

As indicated above, FIGS. 4A-4C are provided as an example. Other examples may differ from what is described with regard to FIGS. 4A-4C.

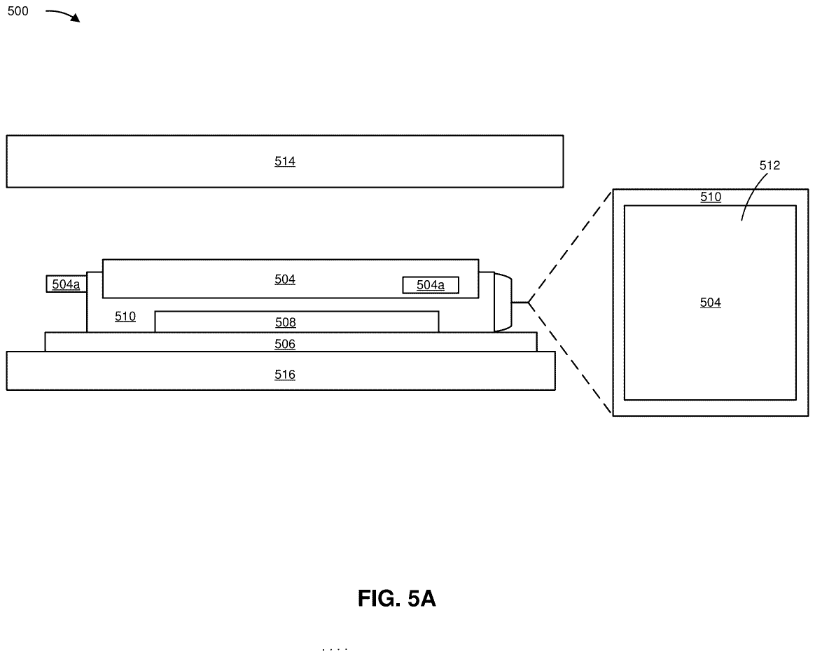

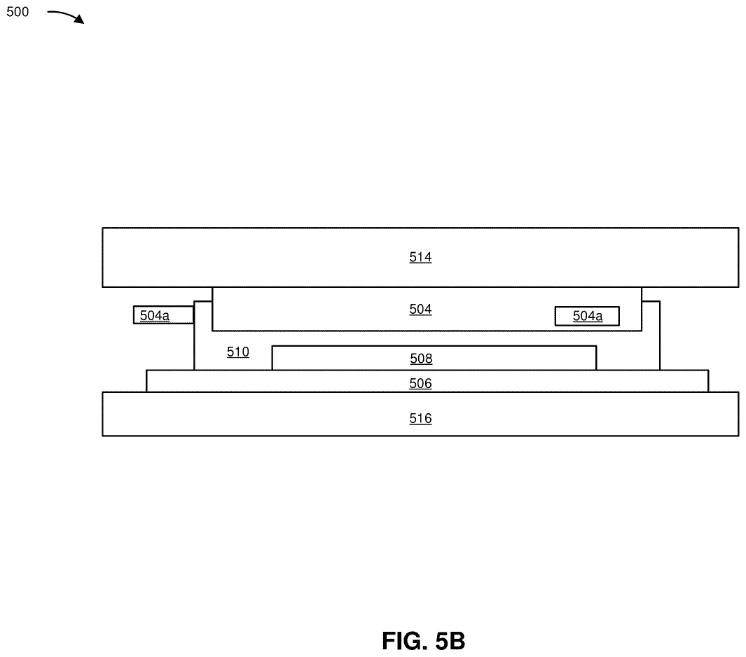

FIGS. 5A-5B are diagrams of an example 500 associated with enhanced encapsulation associated with a semiconductor assembly 502. As shown in FIGS. 5A-5B, the semiconductor assembly 502 may include a first layer 504, a second layer 506, a first material 508, and a second material 510.

The first material 508 may be a TIM including liquid metal droplets dispersed in a polymer, as described in more detail elsewhere herein. The first material 508 may be deposited on the second layer 506, as described in more detail elsewhere herein. In some implementations, the second material 510 may be a hot melt adhesive that is disposed on a surface of the first layer 504 (e.g., before compression forces and/or heat is applied to the semiconductor assembly 502). For example, the hot melt adhesive may be dispensed or patterned along a path to form a continuous or segmented containment region (e.g., shown as a continuous containment region 512 in FIG. 5A).

In some implementations, the first layer 504 may be a heat-generating component including terminals 504a. The heat-generating component may be configured to generate heat (e.g., generated as a result of performing operations, such as power conversion operations, among other examples). The second layer 506 may be configured to dissipate at least a portion of the heat from the heat-generating component (e.g., form the surface of the first layer 504) through the first material 508, as described in more detail elsewhere herein.

In some implementations, compression forces and/or heat may be applied to the semiconductor assembly 502 to transition the semiconductor assembly 502 from a first state representing a first configuration (e.g., a pre-assembled configuration as shown in FIG. 5A) to a second state representing a second configuration (e.g., an assembled configuration as shown in FIG. 5B). In some implementations, the assembled configuration may be a semiconductor package, such as a molded semiconductor package, among other examples.

For example, the compression forces and/or the heat may be applied to the semiconductor assembly 502 via a heat press (e.g., shown as including a top press portion 514 and a bottom press portion 516 in FIGS. 5A and 5B), among other examples. In some implementations, the compression forces and/or the heat may cause the second material 510 to wet to the first layer 504 and the second layer 506. This creates a seal that allows the first material 508 flow and conform to the first layer 504 and the second layer 506 (e.g., within the continuous containment region 512). Accordingly, in some implementations, both the first material 508 and the second material 510 may undergo motion in response to the applied compression forces and/or heat. For example, the first material 508 may flow laterally into the continuous containment region 512 as the second material 510 deforms or redistributes to define or reinforce the continuous containment region 512, among other examples. After compression, a height of the first material 508 and the second material 510 may correspond to the desired BLT, as described in more detail elsewhere herein.

In this way, the first material 508 may be configured to thermally couple the first layer 504 and the second layer 506 to reduce contact resistance and/or thermal resistance between the first layer 504 and the second layer 506. Additionally, the second material 510 may be configured to at least partially encapsulate the first material 508 to enhance stability of the first material 508 and prevent exudation of the liquid metal droplets and/or the polymer from the first material 508 (e.g., under thermal and/or mechanical stress, among other examples).

As indicated above, FIGS. 5A-5B are provided as an example. Other examples may differ from what is described with regard to FIGS. 5A-5B.

Accordingly, and in some implementations, the semiconductor assembly may include a package including an exterior surface (e.g., which may correspond to the first layer 204, the first layer 304, the first layer 404, and/or the first layer 504), a first component (e.g., which may correspond to the heat-generating component 212), a second component (e.g., which may correspond to the second layer 206, the second layer 306, the second layer 406, and/or the second layer 506), a first material (e.g., which may correspond to the first material 208, the first material 308, the first material 408, and/or the first material 508), and a second material (e.g., which may correspond to the second material 210, the second material 310, the second material 410, and/or the second material 510.

The first component may be disposed within the package and may be configured to perform power conversion operations. The exterior surface may be configured to transfer heat generated based on the power conversion operations (e.g., the exterior surface may include a heat transfer region configured to transfer heat generated based on the power conversion operations). The second component may be disposed in proximity to the exterior surface and may be configured to dissipate at least a portion of the heat from the exterior surface. The first material may include liquid metal droplets and a polymer and may be disposed in contact with the exterior surface and the second component to thermally couple the exterior surface and the second component. The first material may be configured to decrease at least one of contact resistance or thermal resistance between the exterior surface and the second component. The second material may be disposed in proximity to the first material and may be configured to at least partially encapsulate the first material to enhance a stability of the first material and to prevent exudation of at least one of the liquid metal droplets or the polymer from the first material based on one or more conditions. For example, the second material 410 may be disposed on the second layer such that the second material is in contact with the second layer. As an example, the second material may be in continuous contact (e.g., complete contact) with the second layer or in semi-continuous contact (e.g. partial contact) with the second layer, among other examples), as described in more detail elsewhere herein.

In some implementations, the package may be a molded structure (e.g., the package may be encapsulated in an epoxy resin, among other examples. In some implementations, the exterior surface is a bottom exterior surface (e.g., such that the semiconductor assembly utilizes single-sided heat dissipation). In some implementations, the exterior surface may include a peripheral edge and the second material may contact a region of the exterior surface that is adjacent to the peripheral edge along at least a portion of a length of the peripheral edge.

Additionally, or alternatively, the first material and/or the second material may be disposed In some implementations, the first material may

The foregoing disclosure provides illustration and description, but is not intended to be exhaustive or to limit the implementations to the precise forms disclosed. Modifications may be made in light of the above disclosure or may be acquired from practice of the implementations.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The hardware and/or software code described herein for implementing aspects of the disclosure should not be construed as limiting the scope of the disclosure. Thus, the operation and behavior of the systems and/or methods are described herein without reference to specific software code-it being understood that software and hardware can be used to implement the systems and/or methods based on the description herein.

When an element is referred to herein as being “connected” or “coupled” to another element, it should be understood that the elements can be directly connected or coupled, or may have one or more intervening elements between them. Similarly, when an element is referred to as being “disposed on”, “disposed over”, or “in proximity to” another element, it should be understood that the element may be in direct physical contact with the other element or may be positioned near or adjacent to the other element with or without intervening layers or structures. In contrast, when an element is referred to as being “directly connected,” “directly coupled,” or “directly disposed on” another element, it should be understood that no intervening elements are present in that direct relationship. However, the existence of a direct connection, coupling, or disposition does not preclude the presence of other, non-direct relationships in which intervening materials or structures may exist.

When an element is referred to herein as being “in contact with” another element, it should be understood that the elements may be in direct physical contact or may be in indirect contact through one or more intervening layers or materials, such as adhesives, coatings, or interface materials. Similarly, when an element is described as being “aligned with” another element, it may be laterally, vertically, or rotationally positioned in relation to that element, either directly or with intervening layers, structures, or materials in between. In contrast, when an element is referred to as being “in direct contact with” or “precisely aligned with” another element, it should be understood that no intervening elements are present (for contact), or that the alignment is exact within manufacturing tolerance (for positioning). However, the presence of a direct or precise relationship does not preclude the existence of other configurations where one or more intervening components are present.

As used herein, the terms “dispose” and/or “disposing” may refer to any action by which a material and/or a component is applied, placed, deposited, or otherwise positioned relative to another material, another component, and/or a surface (e.g., in the context of disposing a material onto a layer of a semiconductor assembly). For example, disposing may include techniques, such as dispensing (e.g., jetting, time-pressure, and/or volumetric dispensing), pick-and-place (e.g., for pads and/or or preformed adhesives), stencil-coating and/or or stencil-printing (e.g., using a patterned aperture to apply a material), screen printing, spray coating, lamination, extrusion, and/or transfer printing, among other techniques. Additionally, the material and/or the component may be disposed using automated, semi-automated, and/or manual equipment and may involve conforming a material to a surface, aligning a material with a region, and/or securing a material through adhesive or physical contact, among other examples. The use of the terms “dispose” and/or “disposing” should therefore be interpreted broadly to encompass a wide range of material placement or application techniques applicable to semiconductor assembly fabrication and/or packaging, among other examples.

As used herein, the terms “cure” and/or “curing” may refer to a chemical process by which a material undergoes cross-linking, polymerization, and/or other molecular transformation that results in a transition from a liquid, paste, and/or semi-solid state to a solid or elastomeric state, among other examples. Curing may include formation of new covalent bonds between reactive components within the material, such as between a binder resin and a curing agent in a thermosetting polymer system, and may result in increased mechanical strength, dimensional stability, and/or resistance to thermal, chemical, or mechanical stress, among other examples. The terms “cure” and/or “curing” may include processes initiated by thermal energy (e.g., heat cure or snap cure), ultraviolet radiation (e.g., ultraviolet cure), moisture exposure, and/or chemical reaction, among other examples. As such, the terms “cure” and/or “curing” are not limited to physical drying mechanisms (e.g., evaporation of a solvent or carrier), but may refer to chemical changes within the material that result in a transformation of structure and/or properties, among other examples. Accordingly, the term “cured,” as used herein, may refer to a state of the material after such a transformation has occurred, and in which the material exhibits intended mechanical and/or functional performance characteristics, among other examples.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set.

As used herein, a phrase referring to “at least one of” a list of items refers to any combination and permutation of those items, including single members. As an example, “at least one of: a, b, or c” is intended to cover a, b, c, a-b, a-c, b-c, and a-b-c, as well as any combination with multiple of the same item. As used herein, the term “and/or” used to connect items in a list refers to any combination and any permutation of those items, including single members (e.g., an individual item in the list). As an example, “a, b, and/or c” is intended to cover a, b, c, a-b, a-c, b-c, and a-b-c.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method, comprising:
disposing a first material, including liquid metal droplets and a polymer, between a first layer and a second layer of a semiconductor assembly,
wherein the first layer includes a region configured to conduct heat generated by a heat-generating component of the semiconductor assembly, and
wherein the second layer is configured to facilitate dissipation of at least a portion of the heat from the region;
disposing a second material in proximity to the first material; and
causing:
the first material to flow and conform to at least a portion of the region and a portion of the second layer such that the first material thermally couples the region and the second layer to decrease at least one of contact resistance or thermal resistance between the region and the second layer, and
the second material to at least partially encapsulate the first material to enhance a stability of the first material and to prevent exudation of at least one of the liquid metal droplets or the polymer from the first material based on one or more conditions.

2. The method of claim 1, wherein the one or more conditions include at least one of:
a thermal condition,
a mechanical condition,
an electrical condition,
an environmental condition, or
an operational condition.

3. The method of claim 1, wherein the first layer includes a peripheral edge, and wherein the second material contacts a region of the first layer that is adjacent to the peripheral edge along at least a portion of a length of the peripheral edge.

4. The method of claim 1, wherein a mass of the first material is approximately 0.7 grams.

5. The method of claim 1, wherein a height of the first material is reduced based on the first material flowing and conforming to the at least the portion of the region and the portion of the second layer.

6. The method of claim 1, wherein the second material is at least one of:
a conformable material,
a deformable material,
a structurally stabilized material, or
a flow-solidifying material a conformal structure.

7. The method of claim 1, wherein the heat-generating component includes a silicon carbide semiconductor device configured for power conversion at operating voltages of at least approximately 200 volts.

8. A semiconductor assembly, comprising:
a first layer;
a heat-generating component disposed on the first layer,
wherein the first layer is configured to transfer heat generated by the heat-generating component;
a second layer configured to facilitate dissipation of at least a portion of the heat from the first layer;
a first material, including liquid metal droplets and a polymer, disposed in contact with the first layer and the second layer to thermally couple the first layer and the second layer,
wherein the first material is configured to decrease at least one of a contact resistance or thermal resistance between the first layer and the second layer; and
a second material, disposed in proximity to the first material, configured to at least partially encapsulate the first material to enhance a stability of the first material and to prevent exudation of at least one of the liquid metal droplets or the polymer from the first material based on one or more conditions.

9. The semiconductor assembly of claim 8, wherein the one or more conditions include at
least one of:
a thermal condition,
a mechanical condition,
an electrical condition,
an environmental condition, or
an operational condition.

10. The semiconductor assembly of claim 8, wherein the first layer includes a region configured to transfer the at least the portion of the heat, and
wherein the first material conforms to the region.

11. The semiconductor assembly of claim 8, wherein the first layer includes a peripheral edge, and
wherein the second material contacts a region of the first layer that is adjacent to the peripheral edge along at least a portion of a length of the peripheral edge.

12. The semiconductor assembly of claim 8, wherein a mass of the first material is approximately 0.7 grams.

13. The semiconductor assembly of claim 8, wherein the first material is configured to flow and conform to the first layer and the second layer in response to application of at least one of a compression force or heat.

14. The semiconductor assembly of claim 8, wherein the heat-generating component includes a silicon carbide semiconductor device configured for power conversion at operating voltages of at least approximately 200 volts.

15. A semiconductor assembly, comprising:
a package including an exterior surface;
a first component, disposed within the package, configured to perform power conversion operations,
wherein the exterior surface is configured to transfer heat generated based on the power conversion operations;
a second component disposed in proximity to the exterior surface, configured to dissipate at least a portion of the heat from the exterior surface;
a first material, including liquid metal droplets and a polymer, disposed in contact with the exterior surface and the second component to thermally couple the exterior surface and the second component,
wherein the first material is configured to decrease at least one of contact resistance or thermal resistance between the exterior surface and the second component; and
a second material, disposed in proximity to the first material, configured to at least partially encapsulate the first material to enhance a stability of the first material and to prevent exudation of at least one of the liquid metal droplets or the polymer from the first material based on one or more conditions.

16. The semiconductor assembly of claim 15, wherein the package is a molded structure.

17. The semiconductor assembly of claim 15, wherein the exterior surface is a bottom exterior surface.

18. The semiconductor assembly of claim 15, wherein a mass of the first material is approximately 0.7 grams.

19. The semiconductor assembly of claim 15, wherein the exterior surface includes a peripheral edge, and
wherein the second material contacts a region of the exterior surface that is adjacent to the peripheral edge along at least a portion of a length of the peripheral edge.

20. The semiconductor assembly of claim 15, wherein the first component is a silicon carbide semiconductor device, and
wherein the power conversion operations are associated with operating voltages of at least approximately 200 volts.
